(19) United States
(12) Patent Application Publication
(10) Pub. No.: US 2008/0118087 A1
(43) Pub. Date: May 22, 2008

(54) MINIATURE SOUND LEVEL DOSIMETER

(75) Inventor: Harold A. Cheyne, Trumansburg, NY (US)

Correspondence Address: GUERIN & RODRIGUEZ, LLP, 5 MOUNT ROYAL AVENUE, MOUNT ROYAL OFFICE PARK, MARLBOROUGH, MA, 01752, US

(73) Assignee: SENSIMETRICS CORPORATION, Somerville, MA (US)

(21) Appl. No.: 11/858,224

(22) Filed: Sep. 20, 2007

Related U.S. Application Data
(60) Provisional application No. 60/866,135, filed on Nov. 16, 2006.

(51) Int. Cl. H03G 5/16

(52) U.S. Cl. 381/107

(57) ABSTRACT

Described is a miniature sound level dosimeter that is less expensive and more user-friendly than conventional sound level dosimeters. The dosimeter includes a frequency-weighting circuit, an envelope follower circuit, an analog-to-digital converter and a microcontroller. The frequency-weighting circuit applies a predetermined frequency-weighting, such as A-weighting, to an electrical signal indicative of the detected sound level to generate a frequency-weighted signal. An analog envelope signal is generated in response to the frequency-weighted signal and converted to a digital output signal. The microcontroller determines the sound dose in response to the digital output signal and a time interval.

### RELATED APPLICATION

This application claims the benefit of the earlier filing date of U.S. Provisional Patent Application Ser. No. 60/866,135, filed Nov. 16, 2006, titled “Miniature Sound Level Dosimeter,” the entirety of which is incorporated herein by reference.

### GOVERNMENT RIGHTS IN THE INVENTION

This invention was made with United States government support under Grant No. R43OH008561-01 awarded by the National Institutes of Occupational Safety and Health. The government may have certain rights in the invention.

### FIELD OF THE INVENTION

The present invention relates generally to a device for measuring a sound dose. More particularly, the invention relates to a miniaturized sound level dosimeter having reduced circuit complexity and cost.

### BACKGROUND OF THE INVENTION

Individuals exposed to high noise levels for extended periods can experience significant hearing loss. Noise-induced hearing loss is a permanent condition that is typically preventable. Employees engaged in certain work activities and individuals participating in certain recreational activities are more likely to experience hearing loss due to repeated exposure to unacceptable noise levels.

Industry and governmental agencies such as the Occupational Safety and Health Administration (OSHA) have established standards for acceptable sound doses in occupational environments. Sound level dosimeters have traditionally been used to monitor occupational environments to determine whether the accumulated noise or sound level to which an employee has been exposed does not exceed established standards. Ideally, each employee is equipped with a personal sound level dosimeter as the sound level generally varies according to the location of the employee relative to noise sources and the time spent in various locations. It can be impractical to equip each employee with a personal dosimeter due to the typical cost and size of conventional sound level dosimeters and the number of employees at an employee facility. Moreover, the complexity of use of conventional sound level dosimeters makes them difficult to operate without significant training.

What is needed is a sound level dosimeter that overcomes the above problems. The present invention satisfies this need and provides additional advantages.

### SUMMARY OF THE INVENTION

In one aspect, the invention features a sound level dosimeter. The dosimeter includes a frequency-weighting circuit, an envelope follower circuit, an analog-to-digital converter (ADC) and a microcontroller. The frequency-weighting circuit is configured to receive an electrical signal from a microphone that is responsive to a sound level at the microphone. The frequency-weighting circuit generates a frequency-weighted signal in response to the electrical signal. The envelope follower circuit is in communication with the frequency-weighting circuit and generates an analog envelope signal in response to the frequency-weighted signal. The ADC is in communication with the envelope follower circuit and generates a digital output signal in response to the analog envelope signal. The microcontroller is in communication with the analog-to-digital converter and is configured to generate a signal indicative of a sound dose.

In another aspect, the invention features a method of determining a sound dose. An electrical signal that is responsive to a sound level is generated and a predetermined frequency-weighting is applied to the electrical signal to generate a frequency-weighted signal. An analog envelope signal that is responsive to the frequency-weighted signal is generated and converted to a digital output signal. The sound dose is determined in response to the digital output signal and a time interval.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon illustrating the principles of the invention.

FIG. 1 shows a functional block diagram of a conventional sound level dosimeter.

FIG. 2 shows a functional block diagram of an embodiment of a sound level dosimeter according to the invention.

FIG. 3 is a schematic circuit representation of a portion of the sound level dosimeter of FIG. 2.

FIG. 4 is a flowchart representation of a method for determining sound level and sound dose according to an embodiment of the invention.

FIG. 5 is an illustration of an embodiment of a sound level dosimeter according to the invention.

FIG. 6 is a flowchart representation of a method for determining sound level and sound dose using the sound level dosimeter illustrated in FIG. 5.

### DETAILED DESCRIPTION

In brief overview, the invention relates to a miniature sound level dosimeter that is substantially less expensive and more user-friendly than conventional dosimeters. The reduction in cost is achieved by a reduction in the number of dosimeter features and simplification of the circuitry used to provide the feature set for the device. Consequently, the dosimeter of the present invention is more affordable and is suitable as a personal monitoring device for individuals who wish to monitor their own risk to hearing health. The dosimeter can be manufactured to meet the specifications set forth in the American National Standards Institute (ANSI) S1.25-1991 document which is incorporated by reference herein. Employees and individuals wearing the dosimeter are able to determine their sound exposure dose and to take appropriate steps to prevent noise-induced hearing loss.

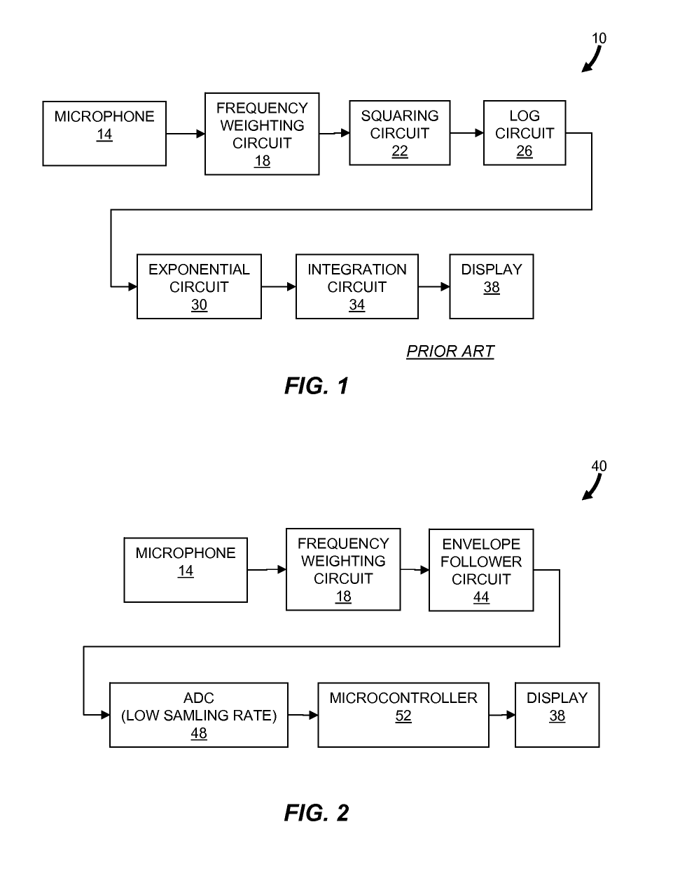

FIG. 1 shows a functional block diagram of a conventional sound level dosimeter 10 as is known in the art. The dosimeter 10 includes a microphone 14 which generates an electrical signal (e.g., a time-dependent voltage) responsive to the sound level. The electrical signal is provided to an amplifier (not shown) for amplification and the amplified signal is provided to a frequency weighting circuit 18. The frequency-weighting circuit 18 has a weighted frequency response defined according to its circuit components. Typically, the weighted frequency response is described by a published standard such as the A-weighted frequency response defined in the ANSI S1.25-1991 document, although other weightings (e.g., C-weighting) or no weighting may be used. A-weighting approximates the frequency sensitivity of the human ear. A-weighting decreases the influence of low and high audible frequencies in comparison to mid-range frequencies where the human ear is most sensitive. The frequency-weighted electrical signal is squared by a squaring circuit 22. A log circuit 26 converts the squared signal to a logarithmic signal, which is received by an exponential circuit 30. An integration circuit 34 integrates the signal received from the exponential circuit 30 for a given time and provides the result of the integration (i.e., the accumulated noise level or sound dose) to a display 38 for presentation to a user. The circuits 18,22,26,30,34 of the conventional dosimeter 10 are implemented using analog circuitry, digital circuitry, or a combination of analog and digital circuitry.

FIG. 2 shows a functional block diagram of an embodiment of a sound level dosimeter 40 according to the invention. Similar to the conventional dosimeter 10 of FIG. 1, the sound level dosimeter 40 includes a microphone 14, a frequency weighting circuit 18 and a display 38. Due to the reduced feature set, the squaring circuit 22, log circuit 26, exponential circuit 30 and integration circuit 34 are replaced by simplified circuitry that includes an envelope follower circuit 44, an analog-to-digital converter (ADC) 48 having a low sampling rate, and a microcontroller 52 or similar module with digital processing capability. The reduced feature set is in compliance with the OSHA occupational noise exposure standard 1910.95 which is incorporated by reference herein. The standard requires only one frequency weighting (A-weighting), one criterion level (90 dBA) and one exchange rate (5 dB). The envelope follower circuit 44, ADC 48 and microcontroller 52 perform alternative signal processing in which most of the processing is performed in the digital domain. Advantageously, the envelope follower circuit 44, ADC 48 and microcontroller 52 are significantly less costly than the components that they replace in a conventional dosimeter.

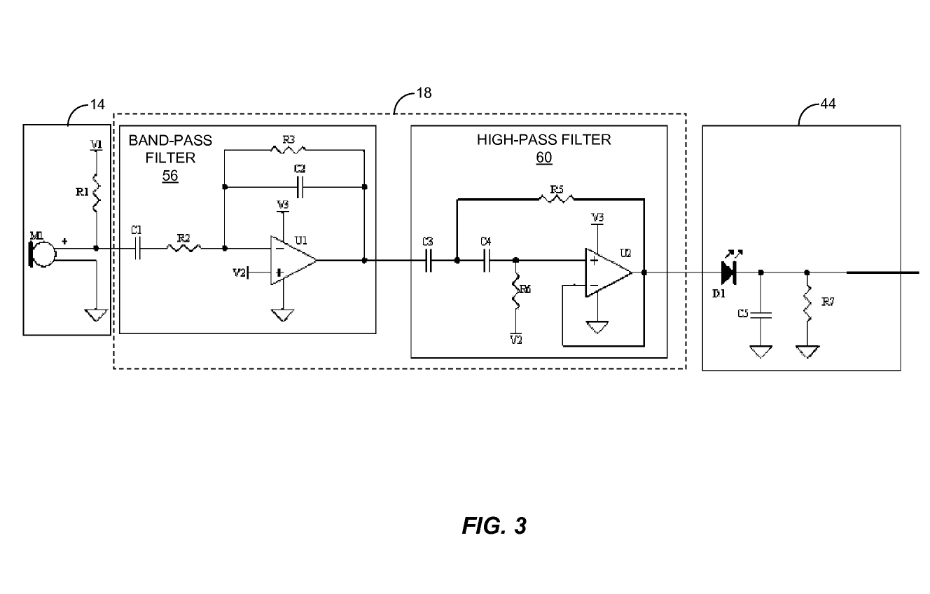

FIG. 3 shows a schematic circuit representation of a portion of the sound level dosimeter 40 of FIG. 2 and includes the microphone 14, frequency-weighting circuit 18 and envelope follower circuit 44.

Preferably, the microphone 14 is an omnidirectional microphone or other microphone having a substantially constant response to incident sound over a wide angular range. Preferably the microphone 14 is integrated in a single package with other components of the dosimeter 40. In alternative embodiments the dosimeter 40 includes an external microphone jack or other electrical connector to permit different types of microphones 14 to be used or to facilitate placement of the microphone 14 at a different location on a user.

The frequency-weighting circuit 18 includes a band-pass filter 56 followed by a high-pass filter 60. Each filter 56,60 includes an operational amplifier, resistors and capacitors specified to achieve the desired frequency response such as the A-weighted frequency response described above.

The components in the illustrated envelope follower circuit 44 include a light-emitting diode (LED), capacitor and resistor. The capacitance and resistance are selected to provide a long time constant relative to the acoustic frequencies passed by the frequency weighting circuit 18.

Referring again to FIG. 2, the ADC 48 has a low sampling rate and samples the signal provided by the envelope follower circuit 44. The ADC 48 can be a sub-audio grade ADC. In one embodiment the sampling rate is approximately 10 Hz.

In one embodiment the microcontroller 52 is a model no. MSP430FG439 ultralow power microcontroller chip (“MSP430”) produced by Texas Instruments (Dallas, Tex.). The small size and low power modes of the MSP430 microcontroller enable a small dosimeter package size and an extended operating time before battery replacement or recharging is required. In addition to its processing capabilities, the MSP430 microcontroller also includes configurable operational amplifiers that can be used with external resistors and capacitors to form the frequency weighting circuit 18 of FIG. 3. The MSP430 microcontroller also includes a 12-bit ADC which can be utilized as the ADC 48 described above. The microcontroller 52 includes memory to store program data and calibration data used during operation as described in more detail below.

The display 38 enables an easily interpretable presentation of the sound dose to the user. For example, the display 38 can show a numerical value or a graphical representation of the sound dose. The display 38 can be a liquid crystal display (LCD), an LED display or other type of compact display for presenting data to a user as in known in the art. In one embodiment the display 38 is an LCD that communicates with an LCD driver integrated to the MSP430 microcontroller described above.

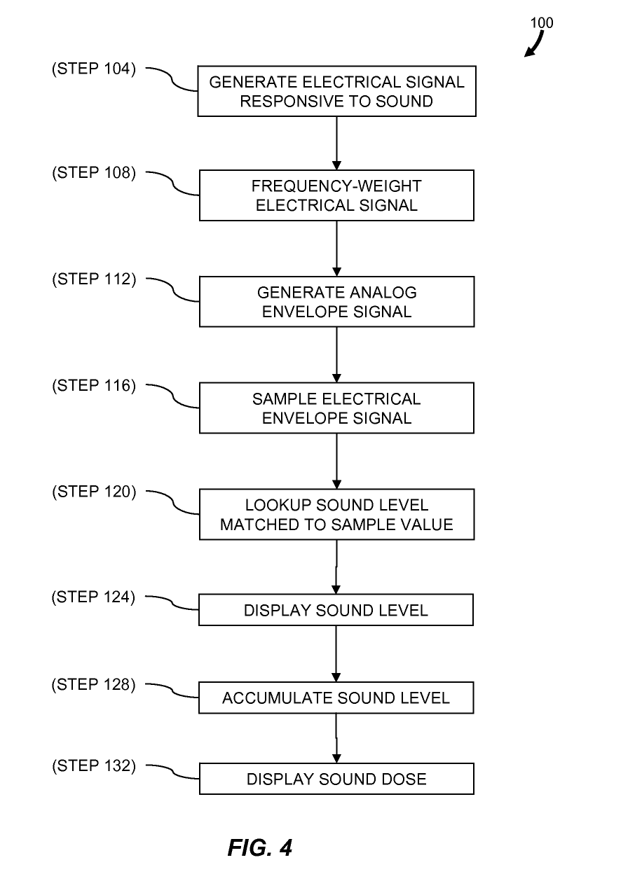

FIG. 4 is a flowchart representation of an embodiment of a method 100 for determining a sound dose according to the invention. Referring to FIG. 2 and FIG. 4, the microphone 14 generates (step 104) an electrical signal in response to received sound. The frequency weighting circuit filters (step 108) the electrical signal according to a desired frequency response (e.g., A-weighting). An analog envelope signal is generated (step 112) that “follows” the slowly varying envelope of the frequency-weighted signal. As used herein, “envelope” means a function that approximately tracks the positive peaks of the more rapidly varying frequency-weighted signal. Thus the analog envelope signal approximates the integration of the sound level over short time intervals that are significantly longer than the periods of audible acoustic frequencies yet small enough to enable accurate determination of the sound level in real time. In some instances a user may be subject to brief impulses of sound or acoustic shocks. Although the analog envelope signal may not accurately track the peaks in such instances, the analog envelope signal does reflect the presence of the impulses due to the integrating nature of the envelope follower circuit 44.

The analog envelope signal is sampled (step 116) by the ADC 48 at a low rate such as 10 Hz. The microcontroller 52 receives a digital output signal from the ADC 48 and performs a lookup (step 120) to find a sound level value stored in flash ROM (or a similar memory module) that corresponds to the value of the digital output signal. The sound level values are written to the flash ROM during manufacture or during a calibration process for each dosimeter 40. The matched sound level value is displayed (step 124), for example in decibels (dB), on an LCD or other display device 38. The sound level is accumulated (step 128) over a known time interval to determine a user's sound dose. The sound dose is displayed (step 132) to the user, for example, as a percent value relative to an acceptable maximum level (100%) for a certain duration.

In an alternative to using a lookup table (see step 120), the flash ROM stores coefficients describing a piecewise polynomial representation of the digital output signal value of the ADC 48 as a function of the sound level. The coefficients can be the same for all dosimeters fabricated with the same circuit components. Alternatively, the coefficients can be determined using a calibration procedure for each dosimeter. The sound level is calculated in near real-time based on the polynomial value corresponding to the value of the digital output signal of the ADC 48. Although only a small number of coefficients specifying the polynomial are stored according to this technique, the computational requirements are increased in comparison to the lookup technique. In yet another alternative, the sound level is determined by interpolation using the data stored in the flash ROM or memory module. For example, a linear interpolation can be performed if the stored data sufficiently represents the sound level as a function of the digital output signal.

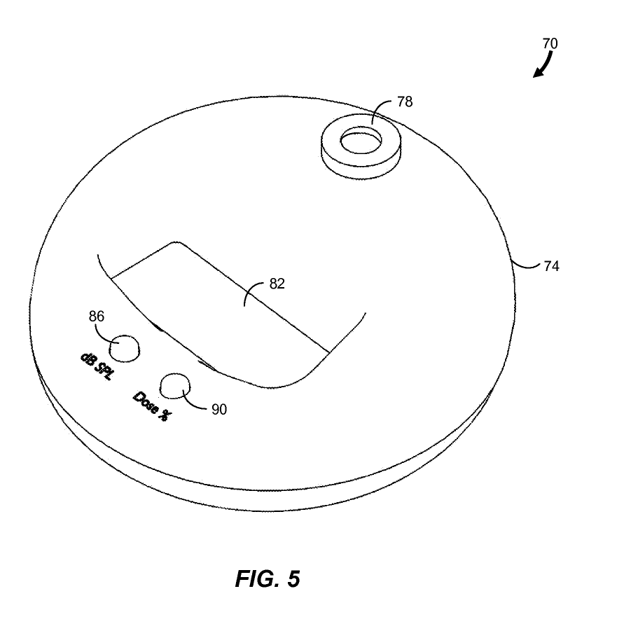

FIG. 5 illustrates an embodiment of the sound level dosimeter of the invention. The dosimeter 70 includes a housing 74 that is sized and shaped similar to a “pocket watch.” In one embodiment the diameter of the housing 74 is approximately 2.5 in. An omnidirectional microphone 78 is provided near the edge of the housing 74. An opening in the housing 74 permits the user to view an LCD 82. Sound level is selected for display in the LCD 82 by depressing an SPL button 86. Alternatively, the sound dose is selected for display in response to pressing a dose button 90. The dosimeter 70 is powered by a lithium coin cell which provides sufficient power for operation of more than one year when used in a low power mode.

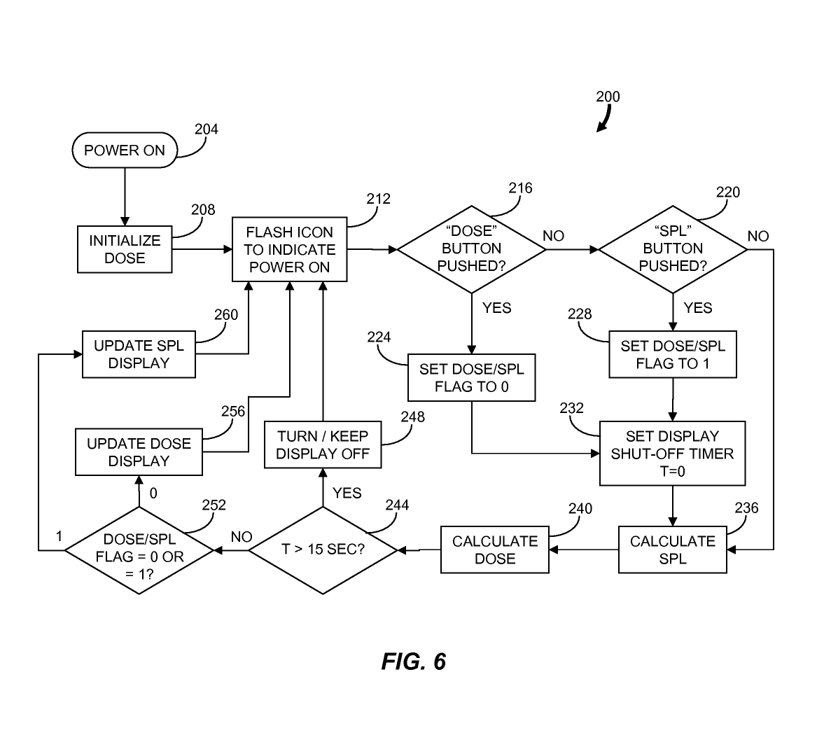

A method 200 for determining sound level and sound dose using the sound level dosimeter illustrated in FIG. 5 is shown by the flowchart of FIG. 6. The dosimeter is powered on (step 204) by a switch and enters a “sleep mode.” In one embodiment, the function of switching on power is achieved by pressing either the SPL button 86 or the dose button 90. A user also presses (step 208) the SPL button 86 or the dose button 90 during sleep mode to activate the dosimeter 70 and to begin dosimetry. The display 82 shows (step 212) a flashing icon to indicate to the user that the dosimeter 70 is in a power on state. A determination is made (steps 216 and 220) as to whether the dose button 90 or SPL button 86 was pressed to select display of the dose or sound level, respectively, and a dose/SPL flag is set (steps 224 and 228) to a value of “0” or “1”, respectively. The method 200 continues by initializing (step 232) a display shut-off timer, calculating the sound level (step 236) and calculating the sound dose (step 240). If it is determined (step 244) that the display 82 has been on for more than 15 seconds, the display 82 is turned off (step 248) to conserve battery power. If the display 82 has not been on for more than 15 seconds, a determination is made (step 252) as to whether the dose/SPL flag is has a “0” value or “1” value, and the display 82 shows (step 256 or step 260) the current dose value or sound level value. The method 200 then returns to step 212 to perform the intervening steps and to display an updated value of the sound dose or sound level.

While the invention has been shown and described with reference to specific embodiments, it should be understood by those skilled in the art that various changes in form and detail may be made therein without departing from the spirit and scope of the invention.

What is claimed is:

1. A sound level dosimeter comprising:
a frequency-weighting circuit configured to receive an electrical signal from a microphone that is responsive to a sound level at the microphone, the frequency-weighting circuit generating a frequency-weighted signal in response to the electrical signal;
an envelope follower circuit in communication with the frequency-weighting circuit and generating an analog envelope signal in response to the frequency-weighted signal;
an analog-to-digital converter in communication with the envelope follower circuit to generate a digital output signal in response to the analog envelope signal; and
a microcontroller in communication with the analog-to-digital converter and configured to generate a signal indicative of a sound dose.

2. The sound level dosimeter of claim 1 further comprising a display in communication with the microcontroller and adapted for displaying the sound dose.

3. The sound level dosimeter of claim 1 further comprising a microphone in communication with the frequency-weighting module.

4. The sound level dosimeter of claim 1 wherein the microcontroller has a memory module configured to store a plurality of digital output signal values and a plurality of sound level values each matched to a respective one of the digital output signal values.

5. The sound level dosimeter of claim 4 wherein the microcontroller performs an interpolation based on the digital output signal and the stored digital output signal values to generate the signal indicative of the sound dose.

6. The sound level dosimeter of claim 1 wherein the microcontroller has a memory module configured to store a plurality of coefficients describing a piecewise polynomial representation of the digital output signal values of the analog-to-digital converter as a function of the sound level at the microphone.

7. The sound level dosimeter of claim 1 wherein the frequency-weighting circuit generates the frequency-weighted signal in response to an A-weighting of the electrical signal from the microphone.

8. A method of determining a sound dose, the method comprising:
generating an electrical signal responsive to a sound level;
applying a predetermined frequency-weighting to the electrical signal to generate a frequency-weighted signal;
generating an analog envelope signal in response to the frequency-weighted signal;
converting the analog envelope signal to a digital output signal; and
determining the sound dose in response to the digital output signal and a time interval.

9. The method of claim 8 wherein the determination of the sound dose is in response to the digital output signal signal, the time interval and calibration data for the sound level.

10. The method of claim 8 wherein the determination of the sound dose is in response to the digital output signal, the time interval and a plurality of coefficients describing a piecewise polynomial representation of the digital output signal values as a function of the sound level.

11. The method of claim 8 wherein the analog envelope signal is converted to a digital output signal at a frequency less than an audible frequency.
